(19) United States
(12) Patent Application Publication
(10) Pub. No.: US 2012/0051083 A1
(43) Pub. Date: Mar. 1, 2012

(54) FLEXIBLE LIGHT SYSTEM FOR ROLL-TYPE DISPLAY AND LIGHTING

(75) Inventors: Sun Tak PARK, Daejeon (KR); Jung Jin Ju, Daejeon (KR); Seung Koo Park, Daejeon (KR); Jin Tae Kim, Daejeon (KR); Min Su Kim, Daejeon (KR)

(73) Assignee: ELECTRONICS AND TELECOMMUNICATIONS RESEARCH INSTITUTE, Daejeon (KR)

(21) Appl. No.: 13/188,908

(22) Filed: Jul. 22, 2011

(30) Foreign Application Priority Data
Aug. 26, 2010 (KR) 10-2010-0083141

(51) Int. Cl. G02B 6/00; H01S 3/00; H01L 33/02

(52) U.S. Cl. 362/553; 362/551; 362/555

(57) ABSTRACT

Provided is a flexible light system including: a light source unit generating a desired optical signal to output; a control unit controlling the optical signal generated from the light source unit; and a panel unit configured of a film having an optical light waveguide combined with the light source unit and transmitting the optical signal generated from the light source unit to a predetermined position and an output terminal outputting the optical signal transmitted through the light waveguide. The flexible light system includes only manual units, such as light waveguides and output terminals, without active elements, in the film of a panel unit, by disposing all driving units outside the panel unit, separate from an optical output panel unit, such that it is possible to implement a roll-type display or a lighting system by using a substrate having flexibility and long-term durability for the film of the panel unit.

### CROSS-REFERENCE TO RELATED APPLICATIONS

This application claims priority under 35 U.S.C. §119 to Korean Patent Application No. 10-2010-83141, filed on Aug. 26, 2010, in the Korean Intellectual Property Office, the disclosure of which is incorporated herein by reference in its entirety.

### TECHNICAL FIELD

The present invention relates to a flexible light system, and more particularly, to a flexible light system that can be used for display terminals, such as PDAs, monitors, TVs, and signboards, and lighting systems, in a roll type.

### BACKGROUND

Flexible displays use thin flexible substrates with long-term durability, which makes it possible to bent and roll the displays without changes in image quality. Flexible display is in its early stage of research and development.

In order to implement a display module that can be rolled in addition to bending, the flexible substrate of the display panel, the driving element controlling electric signals of the pixels in the panel, and the material should be freely bent while the display element generating or controlling visible lights, on the pixel electrode, and the material should have the same properties and the properties should be kept long.

Metal foil, thin film glass, and polymer film have been developed as the material for the flexible substrate, in which the polymer film is under the spotlight as the most possible material. The driving material is the most important part for achieving the flexible display, such that it is of importance to develop a silicon-based material that can be subjected to a wet process for the process of a TFT driving element provided with properties of the flexible substrate at low or normal temperature. Further, although an OTFT (Organic Thin Film Transistor) based on an organic material is being developed, it is required to develop a technology of ensuring long-term durability against curving and bending, because the OTFT made of a low-molecular material is vulnerable particularly to shock.

The e-paper type using an ink ball or a capsule with a diameter of 0.1 mm or less, such as electronic display or printed matters, is used for displaying. LCDs, OLEDs, operating film, and film-reflecting displays are used as the type of electronic display, and four types are used the paper type, that is, electrophoresis, a twist ball, QR-LPD (Quick Response-Liquid Powder Display), and Cholesteric LCD.

It is required for the transmissive LCD most widely used in the display type to develop a backlight suitable for the flexible display and the light source should also have flexibility. Although it is possible to use a direct light source, such as OLEDs, the OLEDs has also weak durability to bending shock on the polymer film, similar to the OTFT, and it seems a little difficult in the present technological level to commercialize large-area displays using the OLEDs as light source. Further, it is required to replace all of the glass substrate made of an inorganic material for TFT-LCD, the a-Si TFT element, and the ITO electrodes with flexible materials and they should have long-term durability. Although a research for using an organic material, such as an organic TFT and a conductive polymer material, on the polymer substrate has been conducted, the performance is lower than the inorganic material, such as silicon ITO, such that it is not easy to implement a roll-type display from the materials.

On the contrary, the e-paper is a reflective display element without self-light source, such that it does not need a flexible light source. Further, since the e-paper type can be implemented on any type of substrates, such as glass, polymer film, and metal, a roll-type display is more likely to be technically implemented in comparison to the transmissive LCD. The transmissive LCD, however, is more advantageous than the reflective e-paper in displaying large images and implementing colors, such that it is strongly required to develop a roll-type display from the transmissive LCD in terms of commerce.

As described above, there are many difficult problems in implementing a roll-type display from the transmissive LCD. The TFT-LCD, light sources, and display element in the driving unit which are not flexible are the largest obstacles in implementing the roll-type display.

Surface-lighting systems using the OLEDs have been proposed as a type of flexible lighting system, but they also has a limit in bending. Further, although it is possible to implement a flexible surface-lighting system, using a flexible backlight, the entire panel can be implemented only in the same color.

Proposed in the related art, methods of implementing a flexible surface-lighting system that guides the visible light by forming light waveguides for red (R), green (G), and blue (B) or arranging optical fiber, and vertically receives the light traveling horizontally or configure pixels by using substances dispersing light when voltage is applied at desired positions (Korean Patent Application No. 10-1998-0052330; PCT/JP 2003/001687; PCT/IB 2005/050646) has been disclosed. Similarly, a method has been proposed which guides the visible light by vertically and horizontally arranging optical fibers and configures pixels by using optical switches between the horizontal and vertical optical fibers at desired positions and substances dispersing light when voltage is applied at desired positions (PCT/US 2006/031738). However, those methods are not suitable for the roll-type display requiring flexibility and long-term durability, because active elements, which are not sufficiently flexible, are disposed on the display substrate to drive the pixels.

Further, a display method using optical fiber cells implementing an image with pixels formed by installing light sources under the panel and interconnecting bunches of 1:1 optical fibers to the light sources has been proposed (Korean Paten Application No. 10-2003-002484), but the method also has difficult in implementing the roll-type display, because the light sources are not flexible.

### SUMMARY

The present invention makes it possible to roll the panel unit by disposing all driving units of a flexible light emitting device outside the panel unit, separate from the optical output panel unit. As described above, since only manual units, such as light waveguides and output terminals, are included in the film of the panel unit, without active elements, a roll-type display or a lighting system is implemented by using a substrate having flexibility and long-term durability for the film of the panel unit.

An exemplary embodiment of the present invention provides a flexible light system including: a light source unit generating a desired optical signal to output; a control unit controlling the optical signal generated from the light source unit; and a panel unit configured of a film having an optical light waveguide combined with the light source unit and transmitting the optical signal generated from the light source unit to a predetermined position and an output terminal outputting the optical signal transmitted through the light waveguide.

In this configuration, the light source unit may include one or more light source generating optical signals and an input unit inputting the optical signal generated from the light sources to the light waveguide of the panel unit, and the light source unit includes an LD, an LED, and a lamp producing white light.

The light source unit may include a light source module that is an assembly of light sources generating optical signals having two or more different wavelengths and an optical combiner that mixes the optical signals having two or more different wavelengths and generated from the light source module, in which it is preferable that the optical signals mixed by the optical combiner are inputted to the light waveguides of the panel unit and the light source module is an LED module that implements full colors by mixing the three primary colors of light and mixing complementary colors.

The optical combiner may include an optical fiber combiner or an optical light waveguide combiner, or may include a first lens making the optical signals from the light source module in parallel light, a wavelength adjusting unit adjusting the wavelength of the optical signals from the first lens, and a second lens collecting the optical signals from the wavelength adjusting unit.

Further, the light source unit may sequentially generate optical signals that are transmitted to the light waveguides, the input unit may be configured to include a beam deflector transmitting the optical signals generated from the light sources to the light waveguides of the panel unit, the beam deflector may include: a third lens making the optical signals from the light source unit in parallel light; a rotary mirror deflecting the optical signals from the third lens to a direction of the corresponding light waveguides to be transferred; and a fourth lens making and transmitting the optical signals from the rotary mirror in parallel light to the corresponding light waveguides to be transferred, and the light source unit is composed of one light source or two or more light sources generating optical signals having different wavelengths, and the light source include a laser or an LED.

Meanwhile, the output terminal formed at the end of the light waveguide and connected with one or more optical light waveguides, the panel unit is made of flexible optical film that is bendable, and the output terminal may be formed of a dispersion pattern or a mirror. The width of the output terminal is not necessarily the same as the width of the optical light waveguide and the size and shape may be change in accordance with the usage.

The film of the panel unit includes a core layer transmitting the optical signals and a clad layer made of a material having reflection ratio lower than the core layer, and may further include a reflective layer that is formed under the film of the panel unit and reflects or scatters light, a dispersing layer formed above or under the film of the panel unit and improving uniformity of intensity distribution of the optical signals outputted through the output terminal, a protective layer formed above the film of the panel unit and protecting the film of the panel unit, and a support layer formed above or under the film of the panel unit and preventing deformation of the film of the panel unit.

Other features and aspects will be apparent from the following detailed description, the drawings, and the claims.

### BRIEF DESCRIPTION OF THE DRAWINGS

FIG. 1 is a diagram schematically illustrating the configuration of flexible light system according to an exemplary embodiment of the present invention;

FIGS. 2 to 4 are diagrams showing examples of a light source module used in a flexible light system according to an exemplary embodiment of the present invention; and

FIGS. 5 to 7 are diagrams showing examples of the film cross-section of a light output panel unit used in a flexible light system according to an exemplary embodiment of the present invention.

### DETAILED DESCRIPTION OF EMBODIMENTS

Hereinafter, exemplary embodiments will be described in detail with reference to the accompanying drawings. Throughout the drawings and the detailed description, unless otherwise described, the same drawing reference numerals will be understood to refer to the same elements, features, and structures. The relative size and depiction of these elements may be exaggerated for clarity, illustration, and convenience. The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

Hereinafter, a flexible light system according to an exemplary embodiment of the present invention is described in detail with reference to the accompanying drawings.

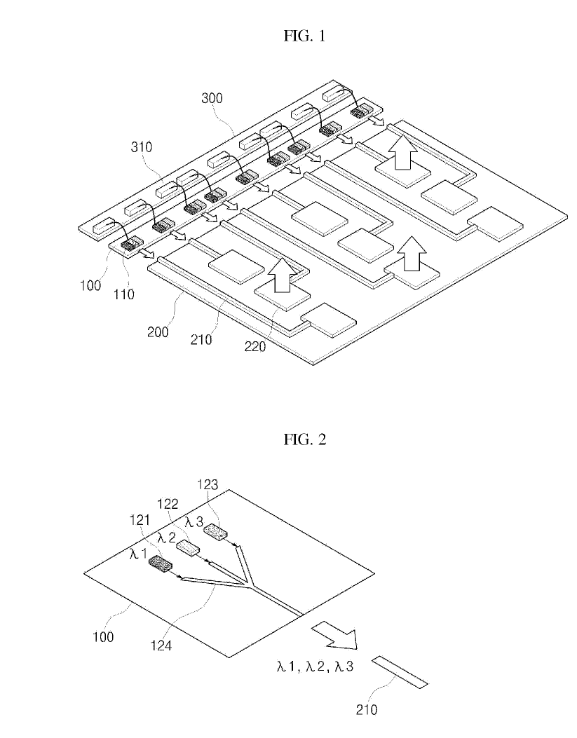

FIG. 1 is a diagram schematically illustrating the configuration of a flexible light system 10, and the flexible light system 10 according to an exemplary embodiment of the present invention may be divided into a light source unit 100, a light output panel unit 200, and a control unit 300.

The light source unit 100 includes one or more light source modules 110 and each of the light source modules 110 generates an optical output signal by generating light and adjusting the intensive of the light, and transmits the optical output signal to an optical light waveguide 210 of the light output panel unit 200. The light output panel unit 200 is formed in film and basically includes the light waveguide 210 and an output terminal 220. The control unit 300 is composed of control modules 310 controlling the light source modules 110, respectively.

The light source module 110 may be a light source having one wavelength in a single-color light system and may be composed of two or more light sources having difference wavelengths when producing various colors, such as full colors. Further, the light source may be formed of a light source capable of adjusting the intensity of light or may be formed to generate a predetermined intensity of light from the light source or adjust the intensity of light, using an optical modulator (not shown).

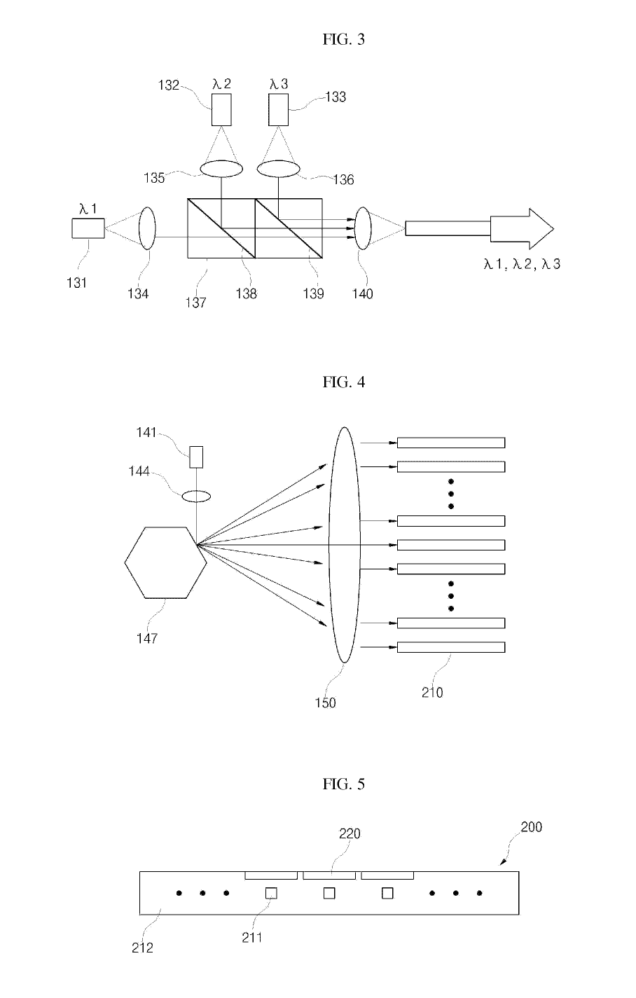

The light source module 110 may be implemented in various types, and examples are shown in FIGS. 2 to 4. FIG. 2 shows a structure using three-wavelength light source and an optical light waveguide type combiner, FIG. 3 shows a structure using a three-wavelength light source and a spatial optical system, and FIG. 4 shows a configuration using one light source and a beam deflector.

FIG. 2 is a diagram showing the configuration of the light source unit 100 including light source modules using a three-wavelength light source and an optical light waveguide type combiner.

As shown in FIG. 2, light source modules 121, 122, 123, and 124 and an optical light waveguide 210 are connected by a 3*1 optical light waveguide type combiner 124 in order to transmit optical signals from the three light sources 121, 122, and 123 having wavelengths of λ1, λ2, and λ3 to generate red, green, and blue light.

As described above, in this configuration, the light sources 121, 122, and 123 should be able to generate light and simultaneously modulate, and when the light source cannot modulate, a specific optical modulator (not shown) should be used between the light sources 121, 122, and 123 and the combiner 124.

Meanwhile, in the embodiment shown in FIG. 2, the number of light source modules is the same as the number of light waveguide 210 or output terminal 220 (FIG. 1).

Further, although the optical light waveguide type combiner 124 is shown in FIG. 2, an optic fiber combiner may be used.

FIG. 3 shows a structure using a spatial optical system, instead of the optical light waveguide type combiner shown in FIG. 2.

As shown in FIG. 3, the light source module is composed of three light sources 131, 132, and 133 having three different wavelengths of λ1, λ2, and λ3, lenses 134, 135, 136, and 140, optical filters 138 and 139, and a filter support 137. The lenses 134, 135 and 136 make and transmit the light emitted from the light sources 131, 132, and 133 in parallel light to the optical filters 138 and 139 and the parallel light from the optical filters 138 and 139 are collected through the lens 140 and then transmitted to the optical light waveguide 210.

The optical filters 138 and 139 are wavelength adjusting members, and the first optical filter 138 transmits λ1 and reflects λ2 and the second optical filter 139 transmits λ1 and λ2 and reflects λ3, such that the optical path of the λ1, λ2, and λ3 are matched to be easily transmitted to the optical light waveguide 210.

In other words, in the embodiment shown in FIG. 3, the optical system composed of the first lenses 134, 135, and 136 making the light emitted from the light sources 131, 132, and 133 in parallel light, the optical filters 138 and 139 that are wavelength adjusting members, and the second lens 140 collecting and transmitting the parallel light from the optical filter 138 and 139 to the optical light waveguide 210 functions the same as the optical light waveguide type combiner 124 shown in FIG. 2.

In the light source unit 100, the optical system shown in FIG. 3 may be used as much as the total number of output terminals, light source arrays as much as the total number of output terminals may be used, and only one spatial optical system may be used.

Meanwhile, the light source unit 100, as shown in FIG. 4, may have a structure where the light source module 141 composed of one light source or light sources having a plurality of wavelengths continuously generates optical signals corresponding to the entire output terminals and the optical signals are transmitted to the light waveguides 210 corresponding to the output terminals, respectively, by the beam deflector 147, such as a rotary mirror.

As shown in FIG. 4, an optical signal generated from the light source 141 is deflected to be transmitted to the beam deflector 147 through the lens 144 and then to the optical light waveguides 210. The beam deflector 147 may be implemented by a rotary mirror etc.

The optical signal deflected to be able to be transmitted to the optical light waveguides 210 is made in parallel light by the lens 150 and outputted to the optical light waveguides 210.

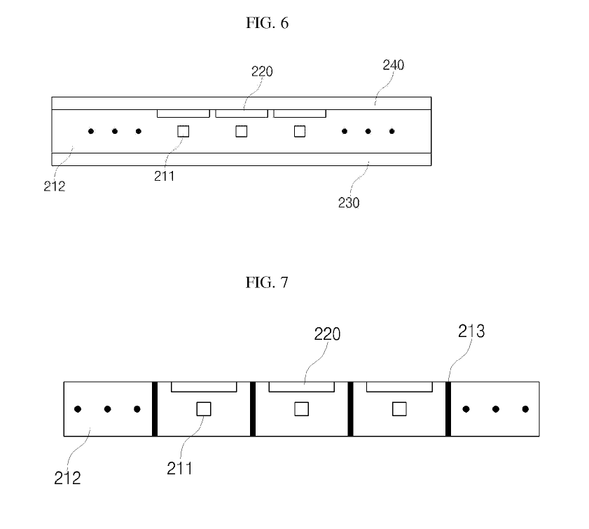

Hereinafter, the configuration of the optical output panel unit 200 will be described in more detail. The plan structure of the optical output panel unit 200 is shown in FIG. 1 and FIG. 5 is a film cross-sectional view of the optical output panel unit.

As described above, a plurality of optical light waveguides 210 and output terminals 220 are formed in the optical output panel unit 200. The plurality of optical light waveguides 210 are independently formed such that the optical signals corresponding to the output terminals are not mixed while being transmitted to the position of the output terminals, and may have difference lengths.

Referring to the cross-sectional structure of the optical output panel unit 200 shown in FIG. 5, the optical light waveguide 210 is basically composed of a core 211 transmitting an optical signal and a clad 212 surrounding the core. In order to transmit the optical signal without a loss, the material for the core 211 generally has refractive index larger than the material of the clad 212. The core 211 may be manufactured in various shapes in accordance with conditions, such as usage and process, and functions, such as a rectangle, a circle, a semicircle, and a lip shape.

The output terminal 220 is formed at the end of the optical light waveguide 210 and formed by a dispersion pattern or a minor to send an optical signal outside the optical output panel unit 200. The dispersion pattern may be manufactured with a rough surface or different refractive ratio distribution therein. It serves to extract the light signal propagated through the light waveguide 210 to the outside of the panel unit 200. The scattered pattern 220 may be disposed above, under, or in the same plan as the core 211 and may be formed in a dispersion pattern layer throughout the optical output panel unit 200. The dispersion pattern may be formed in various shapes to improve light dispersion efficiency and uniformity.

In other words, FIG. 1 shows when the waveguide 210 and the output end 220 is formed on the film of the optical output panel unit 200 and FIG. 5 shows when the waveguide 210 and the output terminal 220 is formed in the optical output panel unit 200, but the interlayer structure of the optical output panel unit 200, the light waveguide 210, and the output terminal 220 is not limited to those shown in FIGS. 1 and 5, an appropriate interlayer structure may be formed, if necessary, in order to send out the optical signal, which is transmitted through the light waveguide to the film shape panel unit, through the output terminal.

Further, although one output terminal 220 corresponds to one optical light waveguide 210 in the embodiment shown in FIG. 1, two or more optical light waveguide may be connected to one output terminal.

The optical output panel unit 200 described above is composed of a sheet of flexible optical film including the optical light waveguide 210 and the output terminal 220 therein, and composed of only manual elements without electrodes or active elements requiring electric operation. Therefore, the optical output panel unit 200 may be formed of film, such as a flexible polymer, such that it is possible to implement roll-type displays or lighting system, and thin displays having a thickness of several millimeters or less or lighting systems. Further, the optical output panel unit 200 having a film shape can be achieved by a low-cost process, such as imprinting, such that it can be easy to be manufactured in large quantities.

It is preferable that the optical output panel unit 200 is formed of a polymer sheet that has excellent mechanical properties, such as bending resistance, and tearing, compressive, and tensile strengths, and durability, is strong against heat, and small absorption in the visible light region.

Meanwhile, as shown in FIG. 6, a reflective layer 230 or a protective layer 240 may be additionally formed above or under the film of the optical output panel unit 200. The reflective layer 230 allows an optical signal scattered down by the dispersion pattern to be sent out again through the output terminal 220 and the protective layer 240 can prevent reflection of light while protecting the optical output panel unit 200 against external shock or scratch. Further, a support layer (not shown) may be further provided to prevent deformation of the film of the optical output panel unit 200 and maintain stability.

Further, as shown in FIG. 7, absorbing layers 213 are inserted on the outside of each output terminal 220 and between the output terminals 220 to prevent undesired optical signals leaking from another output terminal 220 or the optical waveguides 211.

According to the exemplary embodiment of the present invention, since the light source unit composed of active elements for generating and modulating light for optical signals, such as desired images and light to output is separately formed outside the optical output panel unit and the optical output panel unit is formed in a film shape composed of only manual elements not requiring electric operations, such as an optical light waveguide transmitting an optical signal and an output terminal outputting the optical signal to the outside of the panel unit. Therefore, the optical output panel unit can be made of film, such as flexible polymer, such that it is possible to implement roll-type displays or lighting systems, and thin displays having a thickness of several millimeters or less and lighting systems.

Further, the optical output panel unit having a film shape can be achieved by a low-cost process, such as imprinting, such that it can be easy to be manufactured in large quantities.

Further, the intensity of light and colors can be independently adjusted for each output terminal in a lighting system using the present invention, such that the present invention may be used for emotional lighting systems.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A flexible light system comprising:
a light source unit generating a desired optical signal to output;
a control unit controlling the optical signal generated from the light source unit; and
a panel unit configured of a film having an optical light waveguide combined with the light source unit and transmitting the optical signal generated from the light source unit to a predetermined position and an output terminal outputting the optical signal transmitted through the light waveguide.

2. The system of claim 1, wherein the light source unit includes:
one or more light source generating optical signals; and
an input unit inputting the optical signal generated from the light sources to the light waveguide of the panel unit.

3. The system of claim 1, wherein the light source unit includes an LD, an LED, and a lamp producing white light.

4. The system of claim 1, wherein the light source unit includes:
a light source module that is an assembly of light sources generating optical signals having two or more different wavelengths; and
an optical combiner that mixes the optical signals having two or more different wavelengths and generated from the light source module, wherein the optical signals mixed by the optical combiner are inputted to the light waveguides of the panel unit.

5. The system of claim 4, wherein the light source module is an LED module that implements full colors by mixing the three primary colors of light and mixing complementary colors.

6. The system of claim 4, wherein the optical combiner includes an optical fiber combiner or an optical light waveguide combiner.

7. The system of claim 4, wherein the optical combiner includes:
a first lens making the optical signals from the light source module in parallel light;
a wavelength adjusting unit adjusting the wavelength of the optical signals from the first lens; and
a second lens collecting the optical signals from the wavelength adjusting unit.

8. The system of claim 2, wherein the light source unit sequentially generates optical signals that are transmitted to the light waveguides and the input unit is configured of a beam deflector transmitting the optical signals generated from the light sources to the light waveguides of the panel unit.

9. The system of claim 8, wherein the beam deflector includes:
a third lens making the optical signals from the light source unit in parallel light;
a rotary mirror deflecting the optical signals from the third lens to a direction of the corresponding light waveguides to be transmitted; and
a fourth lens making and transmitting the optical signals from the rotary minor in parallel light to the corresponding light waveguides transmitted.

10. The system of claim 8, wherein the light source unit is composed of one light source or two or more light sources generating optical signals having different wavelengths, and the light source include a laser or an LED.

11. The system of claim 1, wherein the output terminal is formed of a dispersion pattern or a mirror, and formed at the end of the light waveguide and connected with one or more optical light waveguides.

12. The system of claim 1, wherein the light waveguides are divided into two or more optical light waveguides in the panel unit, or connected with the output terminal in combination of two or more optical light waveguides.

13. The system of claim 1, wherein the panel unit is made of flexible optical film that is bendable.

14. The system of claim 1, wherein the film of the panel unit includes:
a core layer transmitting the optical signals; and
a clad layer made of a material having reflective index lower than the core layer.

15. The system of claim 1, further comprising a reflective layer that is formed under the film of the panel unit and reflects or scatters light.

16. The system of claim 1, further comprising a scattering layer formed above or under the film of the panel unit and improving uniformity of intensity distribution of the optical signals outputted through the output terminal

17. The system of claim 1, further comprising a protective layer formed above the film of the panel unit and protecting the film of the panel unit.

18. The system of claim 1, further comprising a support layer formed above off under the film of the panel unit and preventing deformation of the film of the panel unit.

19. The system of claim 1, further comprising an absorbing layer that is formed between the output terminals of the panel unit, and prevents a scattered optical signal generated from another output terminal or the light waveguide, except for the optical signal outputted from one output terminal.

20. The system of claim 1, wherein the system is for displaying or lighting.
